(19) United States
(12) Patent Application Publication
(10) Pub. No.: US 2016/0343719 A1
(43) Pub. Date: Nov. 24, 2016

(54) INTERPOSERS FOR INTEGRATED CIRCUITS WITH ONE-TIME PROGRAMMING AND METHODS FOR MANUFACTURING THE SAME

(71) Applicant: GLOBALFOUNDRIES Singapore Pte. Ltd., Singapore (SG)

(72) Inventors: Wei Liu, Singapore (SG); Juan Boon Tan, Singapore (SG); Yi Jiang, Singapore (SG); Danny Shum, Singapore (SG)

(21) Appl. No.: 14/719,499

(22) Filed: May 22, 2015

(51) Int. Cl. H01L 27/112; H05K 1/18; H05K 3/32; H05K 3/40; H01L 23/538; H01L 21/48

(52) U.S. Cl. CPC H01L 27/11206; H01L 23/5384; H01L 23/5382; H01L 21/481; H05K 3/32; H05K 3/4038; H05K 1/18

(57) ABSTRACT

An interposer for an integrated circuit includes a first side and a second side. The interposer includes a substrate and a via disposed in the substrate. A first electrical contact is disposed on the first side. A second electrical contact is disposed on the second side and electrically connected to the via. The interposer also includes a one-time programmable (“OTP”) element electrically connected to the first electrical contact and/or the via.

### TECHNICAL FIELD

The technical field relates generally to interposers for integrated circuits and methods for manufacturing such interposers, and more particularly to 3D integrated circuits with interposers with integrated one-time programming capabilities and methods for manufacturing such integrated circuits.

### BACKGROUND

In many 3D integrated circuits, transistor-based memory cells utilize fuses, thus making the memory cells “one-time programmable”. These fuses are typically disposed in the chips, often adjacent the transistors. This typically requires specific designs and added steps in the manufacturing for each of the chips, which can increase production time and costs. Furthermore, these fuses typically are formed from polycrystalline silicon, which makes their manufacture even more difficult.

As such, it is desirable to provide integrated circuits that allow for one-time programming of memory elements while still utilizing generic chip designs. Other desirable features and characteristics of the various embodiments will become apparent from the subsequent detailed description and the appended claims, taken in conjunction with the accompanying drawings and this background.

### BRIEF SUMMARY

An integrated circuit, according to one embodiment, includes a plurality of transistors. The integrated circuit includes an interposer having a first side and a second side, with the second side disposed opposite the first side. The interposer includes a substrate and a plurality of vias disposed in the substrate. A plurality of first electrical contacts is disposed on the first side. At least one of the first electrical contacts is electrically connected to at least one of the transistors. A plurality of second electrical contacts is disposed on the second side. Each of the second electrical contacts is electrically connected to at least one of the plurality of vias. At least one one-time programmable (“OTP”) element is electrically connected to the first electrical contacts and/or the vias.

A method of manufacturing an interposer having a first side and a second side, according to another embodiment, includes forming a via in a substrate. The method further includes forming a first electrical contact on the first side of the interposer. A second electrical contact is formed on the second side of the interposer and electrically connected to the via. The method also includes forming a OTP element electrically connected to the first electrical contact and/or the via.

An interposer for an integrated circuit, according to another embodiment, defines a first side and a second side. The interposer includes a substrate and a plurality of vias disposed in the substrate. A plurality of first electrical contacts is disposed on the first side of the interposer. At least one of the first electrical contacts is electrically connected to at least one of the transistors. A plurality of second electrical contacts is disposed on the second side of the interposer. Each of the second electrical contacts are electrically connected to at least one of the plurality of vias. The interposer also includes at least one OTP element electrically connected to at least one of the first electrical contacts and at least one of the vias.

### BRIEF DESCRIPTION OF THE DRAWINGS

Other advantages of the disclosed subject matter will be readily appreciated, as the same becomes better understood by reference to the following detailed description when considered in connection with the accompanying drawings wherein:

FIG. 1 is a partial cross-sectional representation of a portion of an integrated circuit of one exemplary embodiment;

FIG. 2 is a top view representation of a fuse utilized for one-time programming according to one exemplary embodiment;

FIG. 3 is a partial electrical schematic diagram of the integrated circuit of FIG. 1 according to one exemplary embodiment;

FIGS. 4A-4G are partial cross-sectional representations of a portion of an interposer of the integrated circuit of FIG. 1 at various stages of fabrication according to one exemplary embodiment; and

FIG. 5 is a flowchart showing a method of manufacturing an interposer according to one embodiment.

### DETAILED DESCRIPTION

The following detailed description is merely exemplary in nature and is not intended to limit the various embodiments and uses thereof. Furthermore, there is no intention to be bound by any theory presented in the preceding background or the following detailed description.

Referring to the figures, wherein like numerals indicate like parts throughout the several views, an interposer 100 for an integrated circuit 102 and method 500 of manufacturing the interposer 100 is shown and described herein.

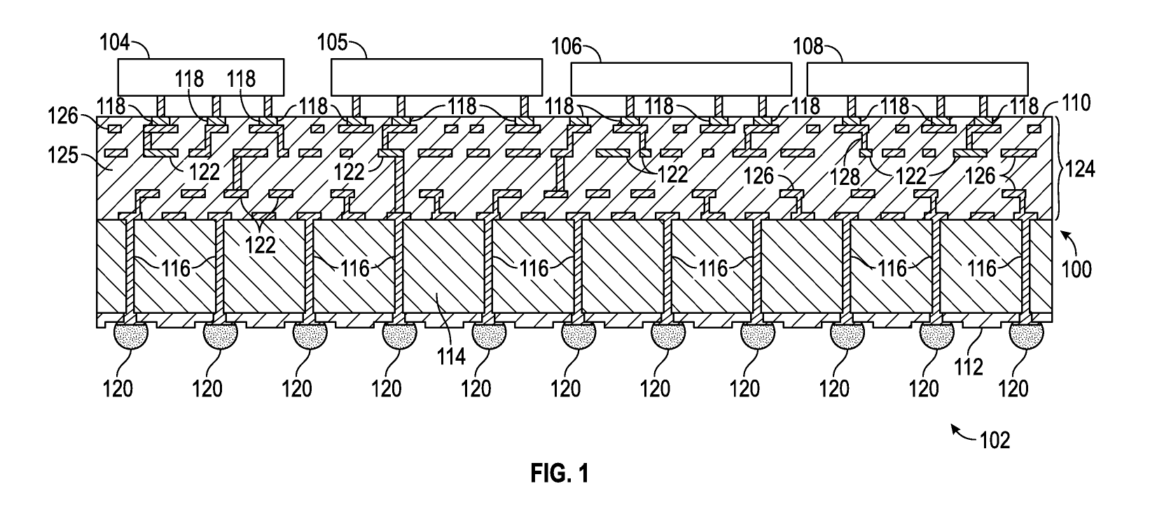

Referring to FIG. 1, the integrated circuit 102 within which the interposer 100 may be utilized may be a three-dimensional (“3D”) integrated circuit, a 2.5D integrated circuit, or other appropriate “stacked” integrated circuits as appreciated by those skilled in the art. The exemplary integrated circuit 102 shown in FIG. 1 includes a first functional chip 104, a second functional chip 105, a first memory chip 106, and a second memory chip 108 electrically connected to the interposer 100. However, it should be appreciated that any number of chips 104, 105, 106, 108 may be utilized in alternate embodiments of the integrated circuit 102.

The interposer 100 defines a first side 110 and a second side 112. The first side 110 and the second side 112 are disposed opposite from one another as shown in FIG. 1. The first side 110 may also be referred to as a “front side” while the second side 112 may also be referred to as a “back side”. In the illustrated embodiment, the first side 110 of the interposer faces the chips 104, 105, 106, 108. However, it should be appreciated that the particular labels of the sides 110, 112 of the interposer 100 are for illustration purposes only and may be reversed or otherwise altered.

The interposer 100 includes a semiconductor substrate 114. As used herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material’” encompasses other materials such as relatively pure and impurity-doped germanium, gallium arsenide, zinc oxide, glass, and the like. An exemplary semiconductor material is a silicon substrate. The silicon substrate may be a bulk silicon wafer or may be a thin layer of silicon on an insulating layer (commonly known as silicon-on-insulator or SOI) that, in turn, is supported by a carrier wafer.

The interposer 100 further include a via 116 disposed in the substrate 114. The via 116 is electrically conductive such that electrical current may be transferred therethrough. For example, the via 116 may include, but is not limited to, copper, other metals, and/or a doped semiconductor.

In the exemplary embodiment, the via 116 extends longitudinally through at least a portion of the substrate 114 from the second side 112 toward the first side 110. As such, in the exemplary embodiment, the via 116 may be referred to as a through-silicon via (“TSV”) 116. Also in the exemplary embodiment, a plurality of through-silicon vias (“TSVs”) 116 are disposed through the silicon substrate 114. The terms TSV and TSVs may be used hereafter with the understanding that only a single TSV 116 is required in some embodiments.

The interposer 100 also includes a first electrical contact 118 disposed on the first side 110 and a second electrical contact 120 disposed on the second side 112. The term “disposed on” does not limit the electrical contacts 118, 120 to be placed completely on top of the respective sides 110, 112. For instance, the contacts may be at least partially embedded in the surface defined by the respective sides 110, 112. An example is shown in FIG. 1, where the first electrical contact 118 is shown below the surface defining the first side 110.

The interposer 100 of the exemplary embodiment includes a plurality of first electrical contacts 118 and a plurality of second electrical contacts 120. The first electrical contacts 118 of the exemplary embodiment may be referred to as conductive pads and may provide electrical connections to the chips 104, 105, 106, 108. The second electrical contacts 120, may be referred to as solder balls and may provide electrical connections to external devices (not shown), e.g., a circuit board. The solder balls may alternatively be referred to as package balls, solder bumps, or solder spheres. In an exemplary embodiment, the solder balls comprise an alloy of tin and lead. However, other materials may also be utilized in forming the solder balls, including, but not limited to, silver and gold.

The electrical contacts 118, 120 of the exemplary embodiment are formed of an electrically-conductive material. Electrically-conductive material, as referred to herein, includes any material having a resistivity of 1×10⁻⁷ ohm*m or less at 20° C. Examples of suitable electrically-conductive materials include metal such as, but not limited to, copper, alloys of tin and lead, or other electrically-conductive metals. In some embodiments, the electrically-conductive material may be about 90 mass percent or more copper, and various copper alloys can be used, some of which include less than 90 mass percent copper. In embodiments, the first electrical contacts 118 may be referred to as conductive pads and may provide electrical connections to the chips 104, 105, 106, 108. In this embodiment, the first electrical contacts 118 include copper. In embodiments, the second electrical contacts 120 may be referred to as solder balls and may provide electrical connections to external devices (not shown), e.g., a circuit board. The solder balls may alternatively be referred to as package balls, solder bumps, or solder spheres. In an exemplary embodiment, the solder balls comprise an alloy of tin and lead. However, other materials may also be utilized in forming the solder balls, including, but not limited to, silver and gold.

The interposer 100 also includes a one-time programmable (“OTP”) element 122. “One-time programming”, as used herein means that the OTP element 122 may have its state changed once in order to program a memory element, e.g., one of the transistors 300, such that a charge may be maintained, or not maintained, in the memory element. In the exemplary embodiment, the OTP element 122 is electrically connected to the first electrical contact 118 and/or the via 116. Of course, if connected to the via 116, the OTP element 122 is also connected to the second electrical contact 120. In the exemplary embodiment, the interposer 100 includes a plurality of OTP elements 122.

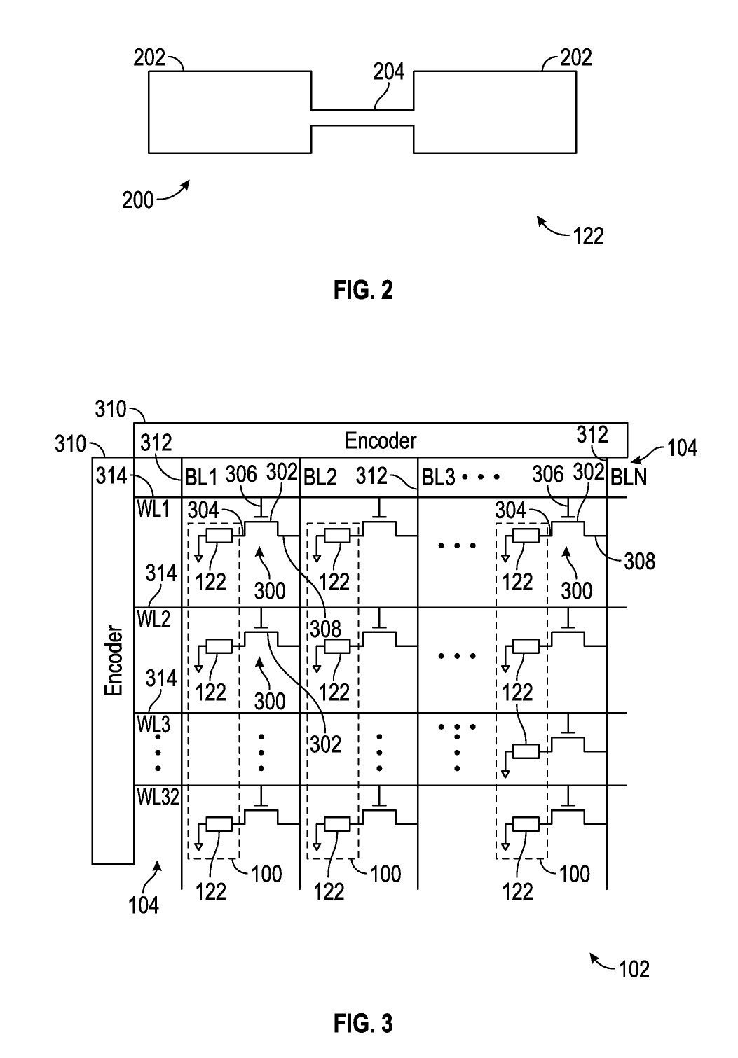

The OTP element 122 may include any suitable material and/or device that allows one-time programming. In the illustrated embodiment, the OTP element 122 is a fuse 200, as shown in FIG. 2. In the illustrated embodiment, the fuse 200 is formed of electrically conductive material such as a metal, e.g., copper. The fuse 200 may be generated utilizing a Damascene process; however, other techniques could be utilized.

The fuse 200 is formed by two end segments 202 and a fuse segment 204 electrically connected to and disposed between the end segments 202. A width of the fuse segment 204 is less than widths of each of the two end segments 202. More specifically, the width of the fuse segment 204 corresponds to the minimum design rule for a metal line. When an electrical current is applied to the fuse 200, the fuse segment 204 will open, thus preventing further current from being applied through the fuse 200.

Referring again to FIG. 1, the interposer 100 may also include a plurality of front side layers 124. These front side layers 124 may include a plurality of metal layers 126 and additional vias 128. These front side layers 124 may be selectively etched, i.e., strategically removed, to provide specific electrical connections and/or electrical routings between the first electrical contacts 118 and the second electrical contacts 120. In the illustrated embodiments, the front side layers 124 are disposed in a dielectric layer 125, e.g., a low-K oxide or a tetraethyl orthosilicate (“TEOS”) oxide.

The OTP elements 122 of the exemplary embodiment are also disposed within these front side layers 124. Accordingly, the OTP elements 122 may not be disposed immediately adjacent to the first electrical contacts 118 and/or the vias 116 to which they are electrically connected, but rather may be physically spaced from the first electrical contacts 118 and/or the vias 116 optionally with one or more metal layers 126 and/or additional vias 128 disposed between the OTP elements 122 and the first electrical contacts 118 or the vias 116.

Referring now to FIG. 3, the integrated circuit 102 may also include at least one transistor 300. In the exemplary embodiment, the integrated circuit 102 includes a plurality of transistors 300. The terms transistor 300 and transistors 300 may be used hereafter with the understanding that only a single transistor 300 is required. Each of the chips 104, 105, 106, 108 may include one or more of the transistors 300. Alternatively, the transistors 300 may be disposed in other parts of the integrated circuit 102, including the interposer 100.

The transistors 300 in the exemplary embodiment are metal-oxide-silicon field-effect transistors (“MOSFETs”) 302. Each MOSFET 302, as shown in the schematic in FIG. 3, includes a source 304, a gate 306, and a drain 308, as is appreciated by those skilled in the art. Each OTP element 122 is electrically connected to either a source 304 or a drain 308 of the associated transistor 300. As such, each MOSFET 302 may be programmed to provide a certain voltage based on the condition of the respective OTP element 122. For instance, the fuse 200 may be opened with a voltage during a write sequence. When a read sequence is utilized, the voltage provided by the MOSFET 302 is based on whether the fuse 200 is opened or closed.

FIG. 3 illustrates transistors 300 disposed in the first functional chip 104. However, as stated above, the transistors 300 may be disposed in any of the chips 104, 105, 106, 108. In the exemplary embodiment, the first functional chip 104 is wire bonded to the interposer 100. More specifically, the first functional chip 104 is wire bonded to the first electrical contacts 118, although it is to be appreciated that the first functional chip 104 may be electrically connected to the interposer 100 through bonds other than wire bonds. The first functional chip 104, which may be a main controller (not separately numbered) for the integrated circuit 102, includes an encoder 310 electrically connected to the transistors 300 via a plurality of bit lines 312 and word lines 314. As such, the encoder 310 is able to select which of the transistors 300 is activated and/or deactivated.

Specifically, in the embodiment shown in FIG. 3, the bit lines 312 are electrically connected to the drains 308 of the MOSFETs 302 while the word lines 314 are electrically connected to the gates 306 of the MOSFETs 302. As such, the encoder 310 may be utilized to select the particular MOSFET 302 to analyze the state of the respective OTP element 122, and thus its programming.

By placing the OTP element 122 in the interposer 100, as opposed to the chips 104, 105, 106, 108, more generic designs for the chips 104, 105, 106, 108 may be utilized, with specific design elements only needing to be changed in the interposer 100 masking. Furthermore, the OTP element 122 may also be utilized to repair the memory elements disposed on the chips 104, 105, 106, 108.

Those skilled in the art appreciate that fabrication of integrated circuits 102 is typically broken down into front-end-of-line (“FEOL”) processing and back-end-of-line (“BEOL”) processing. The formation of the OTP elements 122 may be handled during the BEOL processing, as described in greater detail below. By forming the OTP elements 122 in the interposer 100 during BEOL processing, no additional mask or process development is needed beyond what is typical during BEOL processing. In particular, the OTP elements 122 may be formed by incorporating the design of the OTP elements 122 into the patterning of the appropriate layers during BEOL processing. As such, a significant cost savings may occur by forming the OTP elements 122 in the interposer 100.

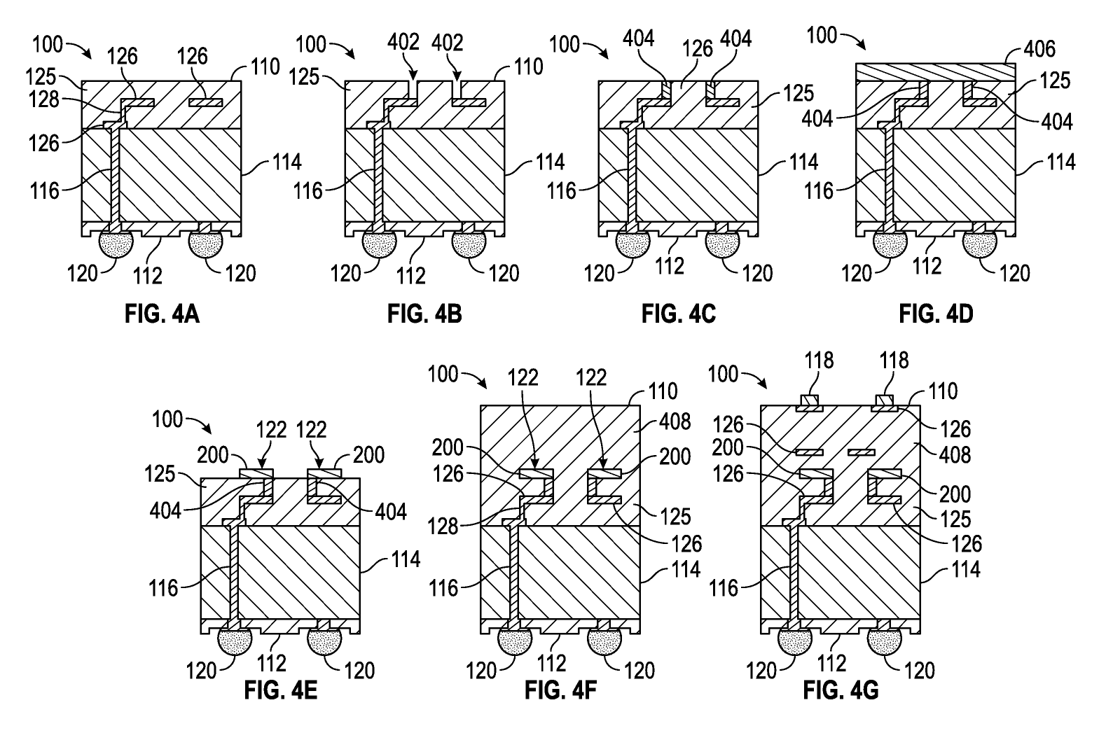

In one embodiment, as shown in FIGS. 4A-4G, the interposer 100 is formed with the fuse 200 (as shown in FIG. 2) as the OTP element 122. FIG. 4A illustrates a plurality of vias 116 disposed through the substrate 114 with each via 116 electrically connected to one of the second electrical contacts 120. A plurality of metal layers 126 are formed from electrically-conductive material, such as copper. The dielectric layer 125 is formed atop the metal layers 126. The dielectric layer 125 may be formed, for example, from TEOS 125. Next, as shown in FIG. 4B, the dielectric layer 125 is etched to expose voids 402 adjacent the metal layers 126 with a surface thereof exposed in the void 402.

Referring now to FIG. 4C, tungsten 404 is deposited in the voids 402 such that the tungsten is electrically connected to the metal layers 126. The exposed side of the dielectric layer 125 then undergoes chemical-metal polishing (“CMP”), also referred to as chemical-metal planarization. Next, as shown in FIG. 4D, a layer of electrically-conductive material 406, such as copper, is deposited. The layer of electrically-conductive material 406 is then etched, as shown in FIG. 3E, to produce the fuses 200 as OTP elements 122. Then, a deposition of another dielectric 408 and CMP is performed, as shown in FIG. 4F. Finally, the BEOL process continues, as shown in FIG. 4G, to produce additional electrically-conductive layers 126, the vias 128, and the first electrical contacts 118.

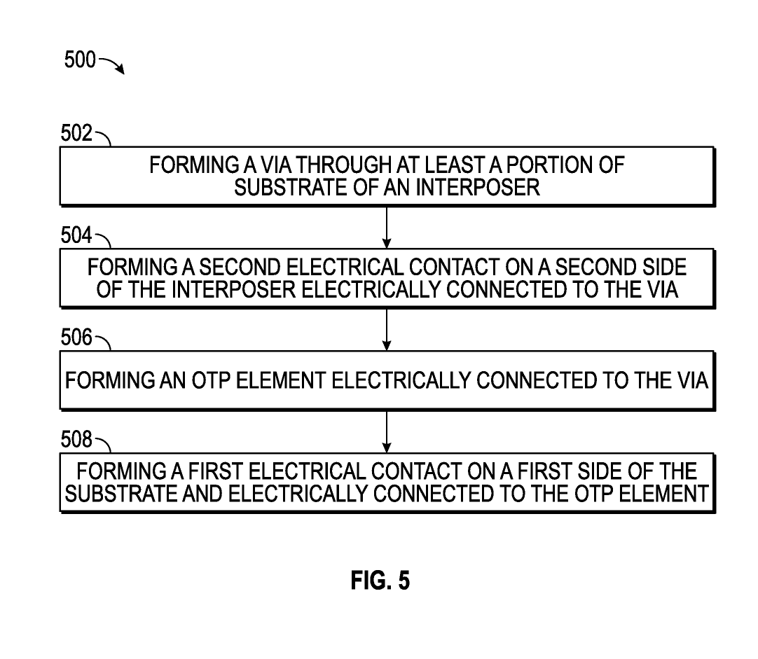

Referring to FIG. 5, a summary of the exemplary method 500 of manufacturing the interposer 100 according to the embodiment as shown in FIGS. 3A-3G is provided. The method 500 includes, at 502, forming the via 116 through at least a portion of the substrate 114. The method 500 also includes, at 504, forming a second electrical contact 120 on the second side 112 of the interposer, where the second electrical contact 120 is electrically connected to the via 116. The method 500 further includes, at 506, forming the OTP element 122 electrically connected to the via 116. The method 500 also includes, at 508, forming a first electrical contact 118 on the first side of the interposer 100 and electrically connected to the OTP element 122.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration in any way. Rather, the foregoing detailed description will provide those skilled in the art with a convenient road map for implementing an exemplary embodiment. It being understood that various changes may be made in the function and arrangement of elements described in an exemplary embodiment without departing from the scope as set forth in the appended claims.

1. An integrated circuit, comprising:
a plurality of transistors; and
an interposer having a first side and a second side disposed opposite said first side, said interposer comprising:
a substrate,
a plurality of vias disposed in said substrate,
a plurality of first electrical contacts disposed on said first side of said interposer, wherein at least one of said first electrical contacts is electrically connected to at least one of said transistors,
a plurality of second electrical contacts disposed on said second side and wherein each of said second electrical contacts are electrically connected to at least one of said plurality of vias, and
at least one one-time programmable (“OTP”) element electrically connected to said first electrical contacts and/or said vias.

2. The integrated circuit as set forth in claim 1, wherein said at least one OTP element comprises a fuse.

3. The integrated circuit as set forth in claim 2, wherein said fuse comprises a metal.

4. The integrated circuit as set forth in claim 2, wherein said fuse comprises copper.

5. The integrated circuit as set forth in claim 1, wherein said OTP element is electrically connected between at least one of said first electrical contacts and at least one of said vias.

6. The integrated circuit as set forth in claim 1, wherein said plurality of transistors comprises a plurality of metal-oxide-silicon field-effect transistors (MOSFETs) each having a source, a gate, and a drain.

7. The integrated circuit as set forth in claim 6, wherein said at least one OTP element is electrically connected to one of said source or said drain of one of said MOSFETs.

8. The integrated circuit as set forth in claim 1, further comprising a functional chip comprising at least one of said plurality of transistors.

9. The integrated circuit as set forth in claim 1, further comprising a memory chip comprising at least one of said plurality of transistors.

10. A method of manufacturing an interposer having a first side and a second side disposed opposite the first side, said method comprising:
forming a first electrical contact on the first side of the interposer;
forming a via in a substrate;
forming a second electrical contact on the second side of the interposer and electrically connected to the via; and
forming a one-time programmable (“OTP”) element electrically connected to the via and/or the first contact.

11. The method as set forth in claim 10, wherein said forming the OTP element comprises forming the OTP element with a fuse.

12. The method as set forth in claim 10, wherein said forming the OTP element comprises forming the OTP element with a metal fuse.

13. The method as set forth in claim 10, wherein forming the OTP element is performed during back-end-of-line (“BEOL”) processing.

14. The method as set forth in claim 10, further comprising forming at least one metal layer electrically connected to and disposed between the via and the OTP element.

15. The method as set forth in claim 10, further comprising forming an electrical connection between said OTP element and said first electrical contact.

16. The method as set forth in claim 15, where said forming an electrical connection between said OTP element and said first electrical contact comprises forming a plurality of metal layers and additional vias.

17. An interposer for an integrated circuit, said interposer defining a first side and a second side, comprising:
a substrate;
a plurality of vias disposed in said substrate;
a plurality of first electrical contacts disposed on said first side of said interposer, wherein at least one of said first electrical contacts is electrically connected to at least one of said transistors;
a plurality of second electrical contacts disposed on said second side of said interposer, wherein each of said second electrical contacts are electrically connected to at least one of said plurality of vias; and
at least one one-time programmable (“OTP”) element electrically connected to at least one of said first electrical contacts and at least one of said vias.

18. The interposer as set forth in claim 17, wherein said at least one OTP element comprises a fuse.

19. The interposer as set forth in claim 18, wherein said fuse comprises a metal.

20. The interposer as set forth in claim 18, wherein said fuse comprises copper.
